(19) United States
(12) Patent Application Publication
(10) Pub. No.: US 2024/0396296 A1
(43) Pub. Date: Nov. 28, 2024

(54) OPTICAL SEMICONDUCTOR DEVICE AND MANUFACTURING METHOD FOR OPTICAL SEMICONDUCTOR DEVICE

(71) Applicant: FURUKAWA ELECTRIC CO., LTD., Tokyo (JP)

(72) Inventors: Kenshiro MATSUSHIMA, Tokyo (JP); Koji HIRAIWA, Chiba (JP); Kazuaki KIYOTA, Tokyo (JP); Akihiro IMAMURA, Chiba (JP)

(73) Assignee: FURUKAWA ELECTRIC CO., LTD., Tokyo (JP)

(21) Appl. No.: 18/794,020

(22) Filed: Aug. 5, 2024

Related U.S. Application Data
(63) Continuation of application No. PCT/JP2023/004171, filed on Feb. 8, 2023.

(30) Foreign Application Priority Data
Feb. 10, 2022 (JP) 2022-019686

(51) Int. Cl. H01S 5/0238; H01S 5/227

(52) U.S. Cl. CPC H01S 5/0238; H01S 5/227

(57) ABSTRACT

An optical semiconductor device includes: a substrate; a first protrusion including a first mesa having a laminate structure and including an active layer; and an alignment marker provided either as a salient portion which protrudes with respect to surrounding portion in the first direction or as a depressed portion which is depressed in an opposite direction of the first direction, and configured to identify a position of the optical semiconductor device in a direction intersecting with the first direction. The alignment marker is shifted with respect to top portion of the salient portion in opposite direction of the first direction or in the first direction with respect to bottom portion of the depressed portion. The alignment marker includes a first lateral face facing toward a direction inclined in an opposite direction of the first direction with respect to a direction orthogonal to the first direction.

This application is a continuation of International Application No. PCT/JP2023/004171, filed on Feb. 8, 2023 which claims the benefit of priority of the prior Japanese Patent Application No. 2022-019686, filed on Feb. 10, 2022, the entire contents of which are incorporated herein by reference.

### BACKGROUND

The present disclosure relates to an optical semiconductor device and a manufacturing method for the optical semiconductor device.

In the related art, as an optical semiconductor device such as a semiconductor laser device or a semiconductor optical amplifier, an optical semiconductor device is known that includes an alignment marker used for the alignment with respect to an optical functional device such as a silicon photonics chip (for example, refer to Japanese Patent Application Laid-open No. 2009-194231).

### SUMMARY

In an optical semiconductor device of that type, for example, if the alignment marker has a low degree of shape accuracy, it results in a low degree of shape accuracy of the image capturing the alignment marker. In turn, it results in a decline in the alignment accuracy of the alignment between the optical semiconductor device and the optical functional device as carried out based on the image processing of the image capturing the alignment marker. In that case, there is a risk of a decline in the coupling efficiency of the light between the optical semiconductor device and the optical functional device.

There is a need for: a new and improved optical semiconductor device in which the required shape accuracy of the alignment marker may be secured with more ease, and in turn the required coupling efficiency of the light between the optical semiconductor device and the optical functional device may be secured with more ease; and a manufacturing method for such an optical semiconductor device.

According to one aspect of the present disclosure, there is provided an optical semiconductor device including: a substrate; a first protrusion protruding from the substrate in a first direction, the first protrusion including a first mesa having a laminate structure, in which a plurality of semiconductor layers are layered on the substrate in the first direction, the first mesa including an active layer as one of the semiconductor layers; and an alignment marker provided either as a salient portion which protrudes with respect to surrounding portion in the first direction or as a depressed portion which is depressed in an opposite direction of the first direction, the alignment marker being configured to identify a position of the optical semiconductor device in a direction intersecting with the first direction, wherein the alignment marker is shifted with respect to top portion of the salient portion in opposite direction of the first direction, or is shifted in the first direction with respect to a bottom portion of the depressed portion, and the alignment marker includes a first lateral face which is facing toward a direction inclined in an opposite direction of the first direction with respect to a direction orthogonal to the first direction.

According to another aspect of the present disclosure, there is provided s manufacturing method for an optical semiconductor device, including: forming, on a substrate, a laminate structure in which a plurality of semiconductor layers are layered in a first direction, the plurality of semiconductor layers including a first semiconductor layer made of a material functioning as an active layer; forming a plurality of mesas protruding from the substrate at a plurality of locations separated in a third direction intersecting with the first direction by partially removing the laminate structure on an opposite side of the structure; forming a current inhibition layer in order to fill a space among the plurality of mesas; forming a conductor layer on the opposite side of the substrate with respect to the first semiconductor layer; and forming a first protrusion including: a first mesa representing one of the plurality of mesas; a part of the current inhibition layer that is adjacent to the first mesa; and a part of the conductor layer that is present on the opposite of the substrate with respect to the first mesa, and forming a second protrusion including a second mesa representing one of the plurality of mesas, the second protrusion functioning as an alignment marker configured to identify a position of the optical semiconductor device in a direction intersecting with the first direction, wherein the alignment marker is shifted with respect to a top portion of the second protrusion in the opposite direction of the first direction, and the alignment marker includes a first lateral face which is facing toward a direction inclined in the opposite direction of the first direction with respect to a direction orthogonal to the first direction.

### BRIEF DESCRIPTION OF THE DRAWINGS

FIG. 1 is an exemplary and schematic cross-sectional view of an optical semiconductor device according to a first embodiment;

FIG. 2 is an exemplary and schematic planar view of some part of the optical semiconductor device according to the first embodiment;

FIG. 3 is an exemplary and schematic cross-sectional view of an intermediate product material obtained during the process of manufacturing the optical semiconductor device according to the first embodiment;

FIG. 4 is an exemplary and schematic cross-sectional view of an intermediate product material obtained at a later stage than the stage illustrated in FIG. 3 during the process of manufacturing the optical semiconductor device according to the first embodiment;

FIG. 5 is an exemplary and schematic cross-sectional view of an intermediate product material obtained at a later stage than the stage illustrated in FIG. 4 during the process of manufacturing the optical semiconductor device according to the first embodiment;

FIG. 6 is an exemplary and schematic planar view of the product material obtained at the same stage as the stage illustrated in FIG. 5 during the process of manufacturing the optical semiconductor device according to the first embodiment;

FIG. 7 is an expanded view of some part of FIG. 6;

FIG. 8 is an exemplary and schematic cross-sectional view of an intermediate product material obtained at a later stage than the stage illustrated in FIGS. 5 and 6 during the process of manufacturing the optical semiconductor device according to the first embodiment;

FIG. 9 is an exemplary and schematic cross-sectional view of an intermediate product material obtained at a later stage than the stage illustrated in FIG. 8 during the process of manufacturing the optical semiconductor device according to the first embodiment;

FIG. 10 is an exemplary and schematic cross-sectional view of an intermediate product material obtained at a later stage than the stage illustrated in FIG. 9 during the process of manufacturing the optical semiconductor device according to the first embodiment;

FIG. 11 is an exemplary and schematic cross-sectional view of an intermediate product material obtained at a later stage than the stage illustrated in FIG. 10 during the process of manufacturing the optical semiconductor device according to the first embodiment;

FIG. 12 is an exemplary and schematic cross-sectional view of an intermediate product material obtained at a later stage than the stage illustrated in FIG. 11 during the process of manufacturing the optical semiconductor device according to the first embodiment;

FIG. 13 is an exemplary and schematic planar view of some part of the optical semiconductor device according to the first embodiment;

FIG. 14 is a schematic diagram of an exemplary image of an alignment marker in the optical semiconductor device according to the first embodiment;

FIG. 15 is an exemplary and schematic planar view of an optical semiconductor device according to a second embodiment;

FIG. 16 is an exemplary and schematic planar view of an optical semiconductor device according to a third embodiment;

FIG. 17 is an exemplary and schematic cross-sectional view of some part of an optical semiconductor device according to a fourth embodiment; and

FIG. 18 is an exemplary and schematic cross-sectional view of some part of an optical semiconductor device according to a fifth embodiment.

### DETAILED DESCRIPTION

Exemplary embodiments of the present disclosure are described below. The configurations explained in the embodiments described below as well as the actions and the results (effects) attributed to the configurations are only exemplary. Thus, the present disclosure may be implemented also using some different configuration than the configurations disclosed in the embodiments described below. Meanwhile, according to the present disclosure, it becomes possible to achieve at least one of various effects (including secondary effects) that are attributed to the configurations.

The embodiments described below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating and among the directions and among the parts. Thus, the ordinal numbers do not indicate the priority or the sequencing.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. In the following explanation, the X direction is referred to as the longitudinal direction or the extension direction, the Y direction is referred to as the short direction or the width direction, and the Z direction is referred to as the layering direction or the height direction.

Meanwhile, the drawings are schematic diagrams intended for use in the explanation. Thus, in the drawings, the scale and the ratio in the vertical and horizontal directions does not necessarily match with the actual objects.

### First Embodiment

### Structure of Optical Semiconductor Device

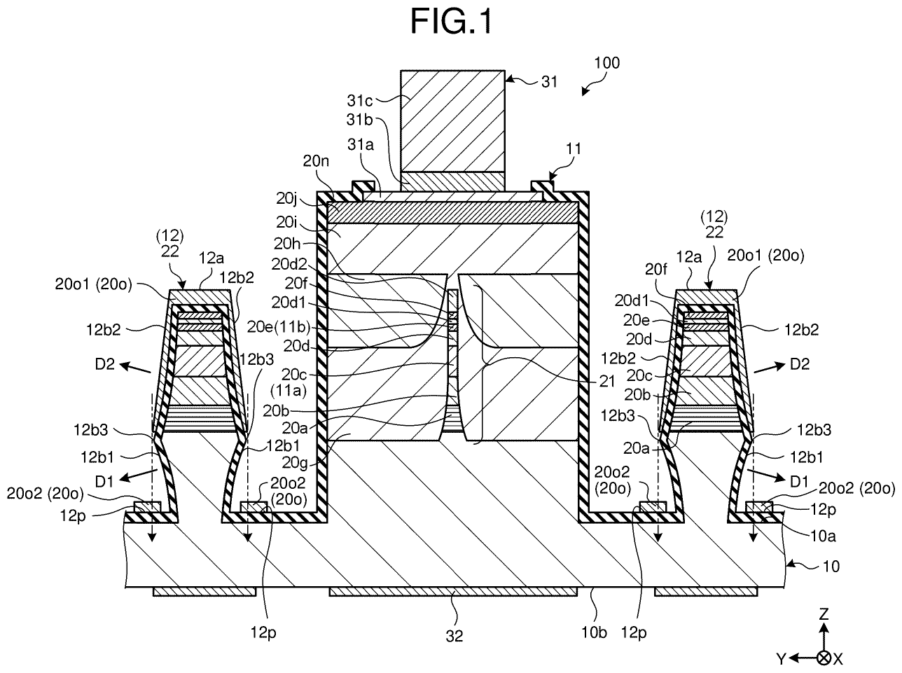

FIG. 1 is a cross-sectional view of an optical semiconductor device 100 according to a first embodiment. As illustrated in FIG. 1, the optical semiconductor device 100 includes a substrate 10, a first protrusion 11, and two second protrusions 12.

The substrate 10 has a substantially constant thickness in the Z direction, and expands across the Z direction. The substrate 10 has faces 10a and 10b. The face 10a is facing toward the Z direction and intersects with the Z direction. The face 10b is positioned on the opposite side of the face 10a, is facing toward the opposite direction of the Z direction, and intersects with the Z direction. The substrate 10 is, for example, made of n-InP. Herein, the face 10a represents an example of a surface.

The first protrusion 11 protrudes in the Z direction from the face 10a of the substrate 10. The two second protrusions 12 also protrude in the Z direction from the face 10a. Of the two second protrusions 12, one second protrusion 12 is positioned away from the first protrusion 11 in the Y direction, and the other second protrusion 12 is positioned away from the first protrusion 11 in the opposite direction of the Y direction. Thus, the first protrusion 11 is positioned in between the two second protrusions 12. Herein, the Z direction represents an example of a first direction, and the Y direction represents an example of a third direction. In the first embodiment, although two second protrusions 12 are included, it is also possible to include a single second protrusion 12 or to include three or more second protrusions 12. When three or more second protrusions 12 are included, the first protrusion 11 may be positioned in between the three or more second protrusions 12.

The first protrusion 11 represents, for example, the part functioning as a laser emission device of a known type; and may also be referred to as a functional unit. The second protrusions 12 represent, for example, the parts used for the alignment with respect to an optical functional device (not illustrated) such as a silicon photonics chip; and represent alignment markers whose images taken by a camera are used in identifying the position of the optical semiconductor device 100 in the directions intersecting with the Z direction. Each second protrusion 12 has a top face 12a that is a planar surface facing toward the Z direction and intersecting with the Z direction. The top face 12a represents an example of an apex portion, and may also be referred to as an end portion or an end face. The top face 12a is entirely covered by a metallic layer 20o1 (20o). In other words, in each second protrusion 12, the metallic layer 20o1 constitutes the top face 12a. The metallic layer 20o has, for example, a laminate structure that includes Ti, Pt, and Au.

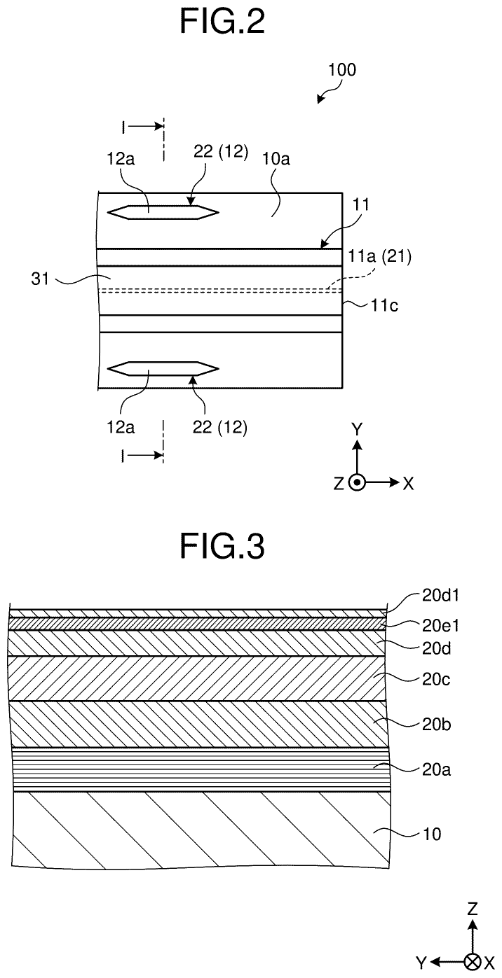

FIG. 2 is a planar view of the optical semiconductor device 100. As illustrated in FIG. 2, the first protrusion 11 and the second protrusions 12 extend on the substrate 10 in the X direction. Meanwhile, FIG. 1 is a cross-sectional view of the optical semiconductor device 100 at an I-I position illustrated in FIG. 2. In the cross-sectional shape illustrated in FIG. 1, the first protrusion 11 and the second protrusions 12 extend in the X direction while having the width in the Y direction and the height in the Z direction. The first protrusion 11 extends in between an end face 11c of the optical semiconductor device 100 in the X direction and the end face (not illustrated) in the opposite direction of the X direction. Each second protrusion 12 extends for a predetermined length at the position that is relatively vicinal to the end face 11c and separated from the end face 11c by a predetermined distance. The end face 11c represents the end face from which a laser light is output. The X direction represents an example of a second direction.

As illustrated in FIG. 1, the first protrusion 11 includes a mesa 21, and each second protrusion 12 includes a mesa 22. The mesa 21 represents an example of a first mesa, and each mesa 22 represents an example of a second mesa.

The mesa 21 and the mesas 22 are manufactured according the same semiconductor process. The mesa 21 as well as each mesa 22 includes a plurality of same semiconductor layers (a first layer 20a to a sixth layer 20f) in a layered form, and partially have the same laminate structure. That is, the same semiconductor layers included in the mesas 21 and 22 are made of the same material. Moreover, the semiconductor layers are arranged in the Y direction, and have the same positions in the Z direction with reference to the face 10a of the substrate 10. However, in each mesa 22, the end portion in the Z direction is removed by means of etching. Hence, the end portion in the Z direction of the mesa 21 includes a semiconductor layer (a layer 20d2 that is farthest from the substrate 10) that is not included in the mesas 22. More particularly, the mesa 21 as well as each mesa 22 includes the first layer 20a, the second layer 20b, the third layer 20c, the fourth layer 20d, the fifth layer 20e, a layer 20d1, and the sixth layer 20f that are layered in the Z direction with reference to the face 10a of the substrate 10. Moreover, in the mesa 21, the layer 20d2 is further included on top of the sixth layer 20f, that is, on the opposite side of the substrate 10 with reference to the sixth layer 20f.

The first layer 20a has a laminate structure including, for example, n-InP and n-InGaAsP. In the mesa 21, the first layer 20a functions as the buffer layer. The second layer 20b is made of n-InP and, in the mesa 21, functions as the cladding layer. Meanwhile, in the mesa 21, the first layer 20a and the second layer 20b may be combinedly referred to as the cladding layer.

The third layer 20c has a laminate structure including n-InGaAsP. In the mesa 21, the third layer 20c operates as an active layer 11a. The third layer 20c represents an example of a first semiconductor layer.

The fourth layer 20d is, for example, made of p-InP. The fifth layer 20e includes, for example, first parts that are arranged at regular intervals in the X direction and that are made of p-InGaAsP; and second parts that fill the gaps between the neighboring first parts in the X direction and that are made of p-InP. In the mesa 21, the fifth layer 20e functions as a diffraction grating layer 11b. On the opposite side of the substrate 10 with reference to the fifth layer 20e, the layer 20d1 is formed that is made of the same material as the fourth layer 20d. Thus, the fifth layer 20e is sandwiched between the fourth layer 20d and the layer 20d1.

The sixth layer 20f is, for example, made of p-InGaAsP. The sixth layer 20f is, what is called, a quaternary layer and has the property of neither being etchable by a predetermined etching solution (for example, hydrochloric acid), which is usable in the etching of other semiconductor layers (for example, the cladding layer made of InP), nor being etchable by an etching gas (for example, a mixed gas of methane and hydrogen); or has the property of having a sufficiently small ratio of the etching rate (for example, 1/10 or lower) as against the etching rate of the other semiconductor layers. Herein, the sixth layer 20f may also be referred to as an etch stop layer.

In the mesa 21, the sixth layer 20f is positioned on the opposite side of the substrate 10 with reference to the third layer 20c that functions as the active layer 11a.

The mesa 22 constitutes each second protrusion 12. The sixth layer 20f is exposed at the end portion in the Z direction of each mesa 22, that is, each second protrusion 12; and the top face 12a is formed. As is clear from FIG. 1, in the first embodiment, on the sixth layer 20f of each second protrusion 12, no other layer such as a passivation layer is formed. However, alternatively, such another layer may also be formed.

In the mesa 21, on the opposite side of the substrate 10 with reference to the sixth layer 20f, the layer 20d2 is formed with the same material as the fourth layer 20d.

In the first protrusion 11, the mesa 21 is enclosed by current inhibition layers 20g and 20h that are placed adjacent to each other either in the Y direction or in the opposite direction of the Y direction; and is enclosed by a cladding layer 20i that is placed in the Z direction. The current inhibition layer 20g is, for example, made of p-InP; and the current inhibition layer 20h is, for example, made of n-InP. The cladding layer 20i is, for example, made of p-InP.

On the opposite side of the substrate 10 with reference to the cladding layer 20i, a contact layer 20j is formed. The contact layer 20j is, for example, made of p-InGaAsP. On the contact layer 20j, an electrode 31 is disposed. The electrode 31 is a P-side electrode that is positioned away from the active layer 11a in the Z direction. The electrode 31 is, for example, layered from the contact layer 20j in the Z direction; and includes a base layer 31a, a barrier layer 31b, and a thick-film layer 31c. The base layer 31 has, for example, a laminate structure that includes Au and AuZn. The barrier layer 31b includes, for example, Pt. The thick-film layer 31c includes, for example, Au. Herein, the electrode 31 represents an example of a first electrode.

In the portion including the cross-sectional surface in FIG. 1, the optical semiconductor device 100 is covered by an insulating film 20n except for some part of the apex portion of the first protrusion 11. The insulating film 20n is, for example, made of SiN. Inside the opening formed on the apex portion of the first protrusion 11, the electrode 31 is electrically connected to the contact layer 20j.

On the face 10b of the substrate 10, an electrode 32 is disposed. The electrode 32 is an N-side electrode having, for example, a laminate structure including AuGe, Ni, and Au.

Each second protrusion 12 has lateral faces 12b1 that are facing toward a direction D1 inclined in the opposite direction of the Z direction with respect to the direction orthogonal to the Z direction; and has lateral faces 12b2 that are facing toward a direction D2 inclined in the Z direction with respect to the direction orthogonal to the Z direction. With reference to the top face 12a, the lateral faces 12b1 and 12b2 are shifted in the opposite direction of the Z direction. The lateral faces 12b2 are positioned in between the top face 12a and the lateral faces 12b1, and are positioned on the opposite side of the substrate 10 with reference to the lateral faces 12b1. Herein, the lateral faces 12b1 represent examples of a first lateral face, and the lateral faces 12b2 represent examples of a second lateral face.

The optical semiconductor device 100 includes the metallic layer 200, which covers the second protrusions 12 and covers surrounding portions 12p of the second protrusions 12. In the first embodiment, the metallic layer 200 includes the metallic layer 2001 that covers the top face 12a and the lateral faces 12b2; and a metallic layer 2002 that covers (the insulating film 20n which covers) the face 10a in the surrounding portion 12p of the concerned second protrusion 12. Moreover, as is clear from dash-double-dot lines illustrated in FIG. 1, in the Z direction, the metallic layer 2002 is formed to overlap with end edges 12b3 of the lateral faces 12b1 in the Z direction.

### Manufacturing Method for Optical Semiconductor Device

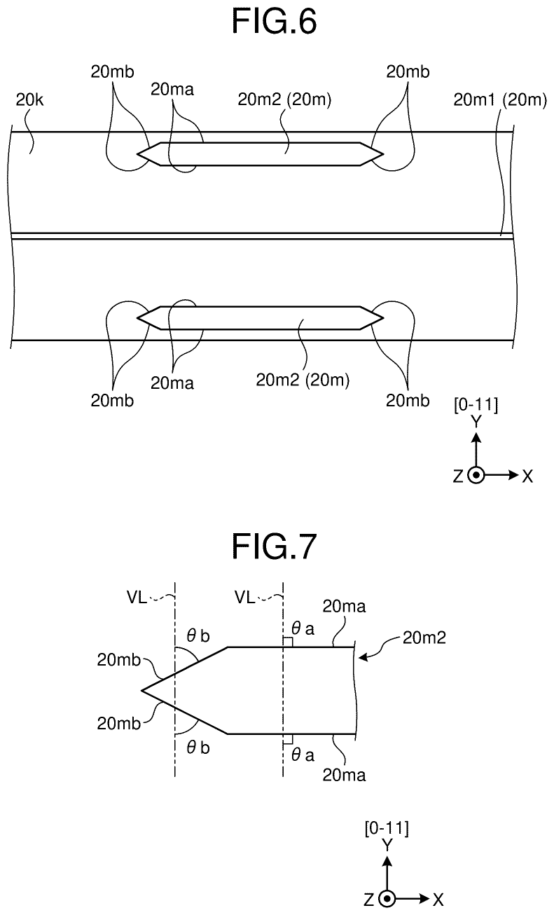

FIGS. 3 to 12 are diagrams illustrating the intermediate product materials obtained during each manufacturing process in the manufacturing method for the optical semiconductor device 100. FIGS. 3 to 5 and FIGS. 8 to 12 are cross-sectional views of the product materials. FIG. 6 is a planar view of the product material obtained at the same stage as the stage illustrated in FIG. 5. FIG. 7 is an expanded view of some part of FIG. 6. Herein, a product material may also be referred to as a laminate structure.

Firstly, as illustrated in FIG. 3, on the face 10a of the substrate 10 representing a wafer, the following layers are formed by means of crystalline growth: the first layer 20a; the second layer 20b; the third layer 20c; the fourth layer 20d; a layer 20e1 responsible for the first parts of the diffraction grating layer 11b; and the layer 20d1 formed on the diffraction grating layer 11b. The layer 20e1 is made of p-InGaAsP. The third layer 20c functions as the active layer 11a in the mesa 21.

The substrate 10 (wafer) and the semiconductor layers that are layered on the substrate 10 have a zinc blende structure. The surface (principal surface) of the wafer and the face 10a of the substrate 10 represent (100) faces. Herein, (100) represents the Miller index indicating the crystalline orientation of the normal direction of a face.

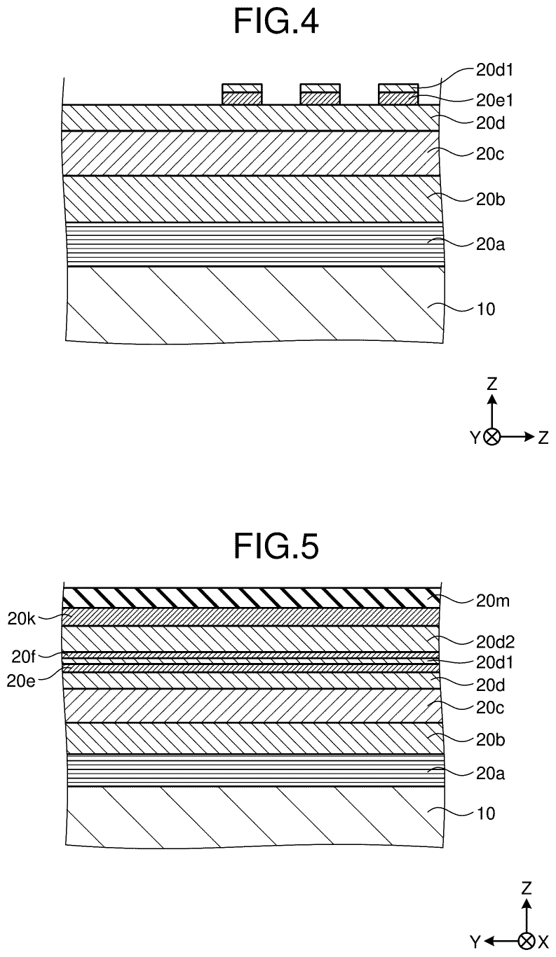

Then, as illustrated in FIG. 4, etching is performed on the product material illustrated in FIG. 3, and the layers 20e1 and 20d1 are selectively removed at intervals in the X direction. Subsequently, the removed portions are filled with p-InP. It results in the formation of the fifth layer 20e, which functions as the diffraction grating layer 11b in the mesa 21, and in the formation of the layer 20d1 on the fifth layer 20e.

Then, as illustrated in FIG. 5, on the layer 20d1 that is formed on the fifth layer 20e; the sixth layer 20f, the layer 20d2, a sacrificial layer 20k, and a mask layer 20m are formed. The sacrificial layer 20k is, for example, made of InGaAsP; and the mask layer 20m is, for example, made of SiN.

The mask layer 20m illustrated in FIG. 5 is formed to have a planar shape as illustrated in FIG. 6. The mask layer 20m includes a mask layer 20m1 formed on the mesa 21, and includes mask layers 20m2 formed on the mesas 22. In the planar view from the opposite direction of the Z direction, the mask layers 20m2 that are formed on the mesas 22 have a polygonal shape. In the first embodiment, as an example, the mask layers 20m2 have a hexagonal shape elongated in the X direction. However, that is not the only possible case. Herein, the mask layer 20m represents an example of a mask.

FIG. 7 is an expanded view of some part of FIG. 6. As illustrated FIG. 7, in the planar view, sides 20ma and sides 20mb of the polygonal shape of the mask layer 20m2 are not parallel to virtual lines VL extending in a [0-11] direction (the Y direction). More particularly, a minimum angle θa made by each side 20ma, which runs substantially along the X direction representing the longitudinal direction of the concerned mesa 22 (the second protrusion 12), with the virtual line VL has the absolute value substantially equal to 90°. Moreover, a minimum angle θb made by each side 20mb, which constitutes an apical portion in the X direction and the opposite direction of the X direction, and the virtual line VL has the absolute value substantially equal to 55°. The reason for having such a shape is explained later. Herein, [0-11] represents the Miller index indicating the crystalline orientation.

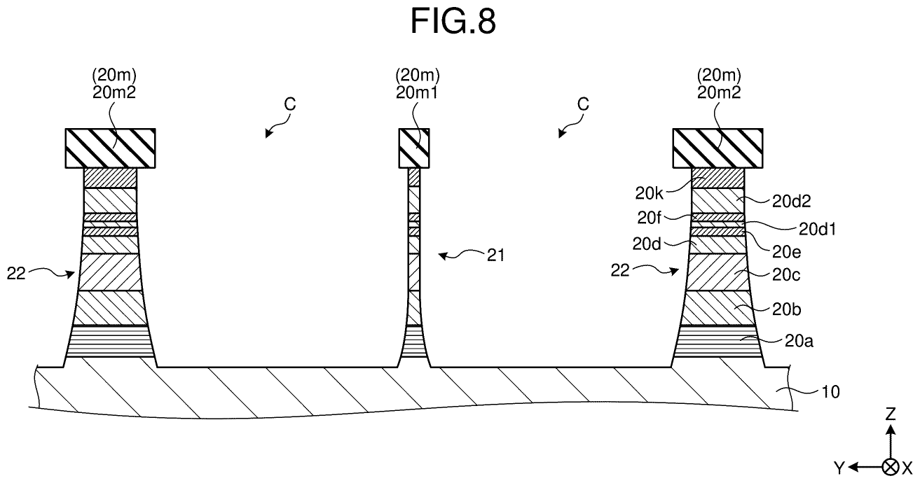

Subsequently, as illustrated in FIG. 8, from the product material illustrated in FIG. 5, the part that is not covered by the mask layer 20m is removed by means of etching. As a result, concave portions C, the mesa 21, and the mesas 22 are formed on the opposite side of the Z direction with reference to the mask layer 20m and the sacrificial layer 20k. That is, in the product material illustrated in FIG. 5, as a result of partial removal on the opposite side of the substrate 10, a plurality of mesas 21 and 22 is formed on the substrate 10, and the concave portions C are formed in between the mesas 21 and 22. Meanwhile, at the time of performing etching, the sacrificial layer 20k assumes the role of adjusting the lateral-face shape of the mesas 21 and 22 to be gentle curved surfaces running along the Z direction.

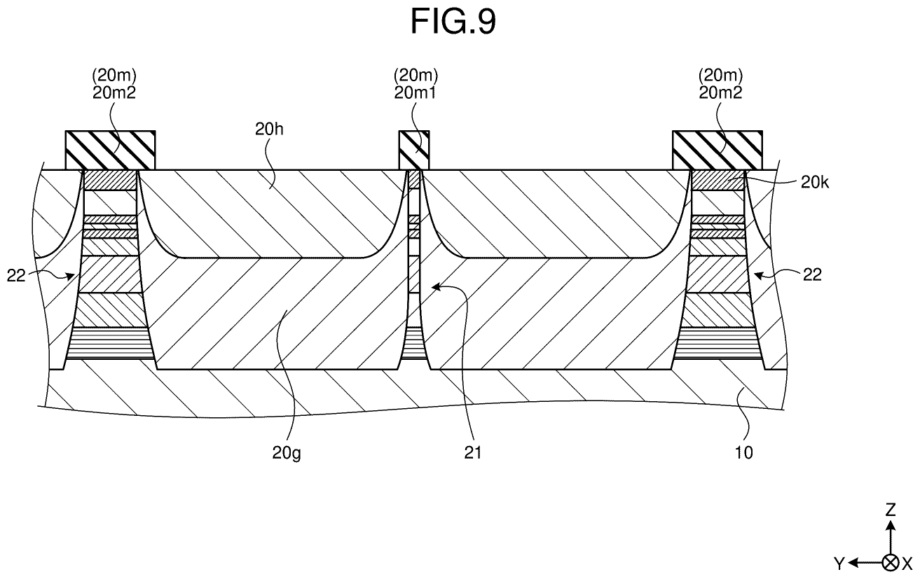

Then, as illustrated in FIG. 9, the current inhibition layers 20g and 20h are formed to fill the concave portions C (see FIG. 8) present between the mesas 21 and 22.

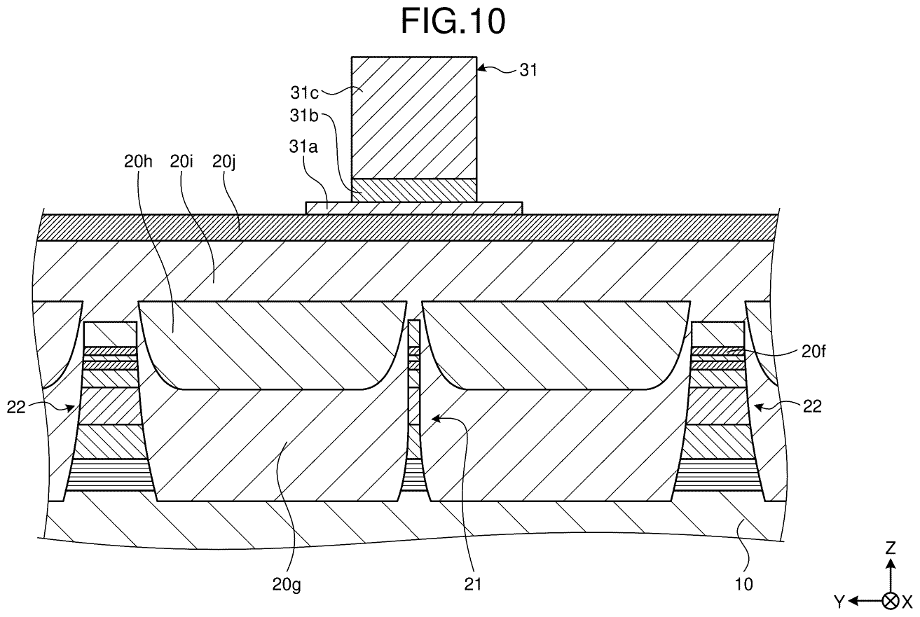

Subsequently, as illustrated in FIG. 10, the mask layer 20m and the sacrificial layer 20k are removed from the product material illustrated in FIG. 9; and the cladding layer 20i, the contact layer 20j, the base layer 31a, the barrier layer 31b, and the thick-film layer 31c are formed on the opposite side of the substrate 10 in the product material. Herein, the contact layer 20j, the base layer 31a, the barrier layer 31b, and the thick-film layer 31c represent examples of a conductor layer.

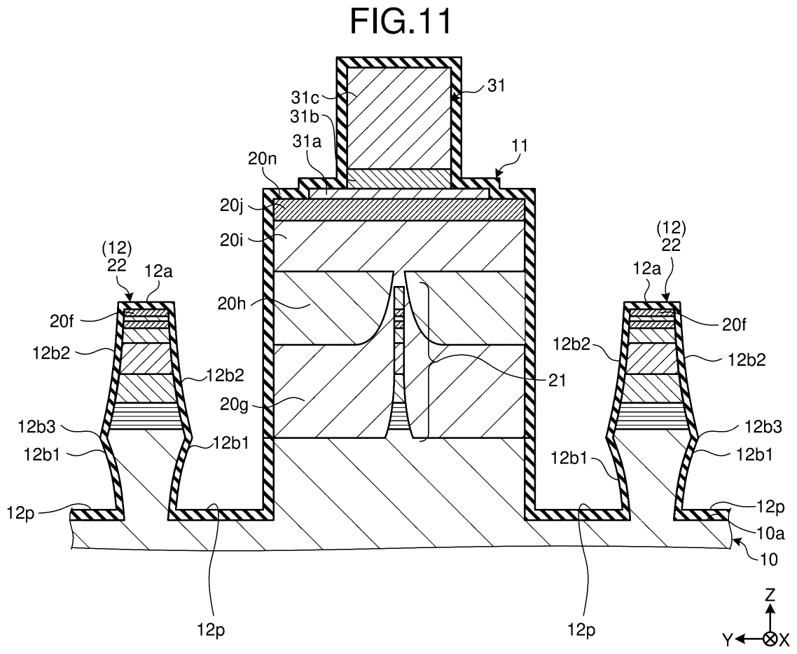

Subsequently, the part that is present on the opposite side of the substrate 10 and between the mesa 21 and the mesas 22 is removed by means of etching using a predetermined etching solution or a predetermined etching gas; and the insulating film 20n is used to cover the entire surface. As a result, as illustrated in FIG. 11, the first protrusion 11 including the mesa 21 (but without the insulating film 20n) is formed, and the second protrusions 12 representing the mesas 22. The first protrusion 11 includes the mesa 21; includes that part from among the current inhibition layers 20g and 20h, the cladding layer 20i, and the contact layer 20j which is adjacent to the mesa 21 (i.e., the surrounding part of the mesa 21 that covers the mesa 21); and includes the electrode 31.

At the time of performing etching in order to obtain the product material illustrated in FIG. 11 from the product material illustrated in FIG. 10, in each mesa 22 (the second protrusion 12), the sixth layer 20f functions as the etch stop layer and becomes exposed in the top face 12a in the Z direction of the second protrusion 12. Moreover, as a result of performing etching, the lateral faces 12b1 of each second protrusion 12 are formed. The lateral faces 12b2 are formed at the time of performing etching in order to obtain the product material illustrated in FIG. 8 from the product material illustrated in FIG. 5.

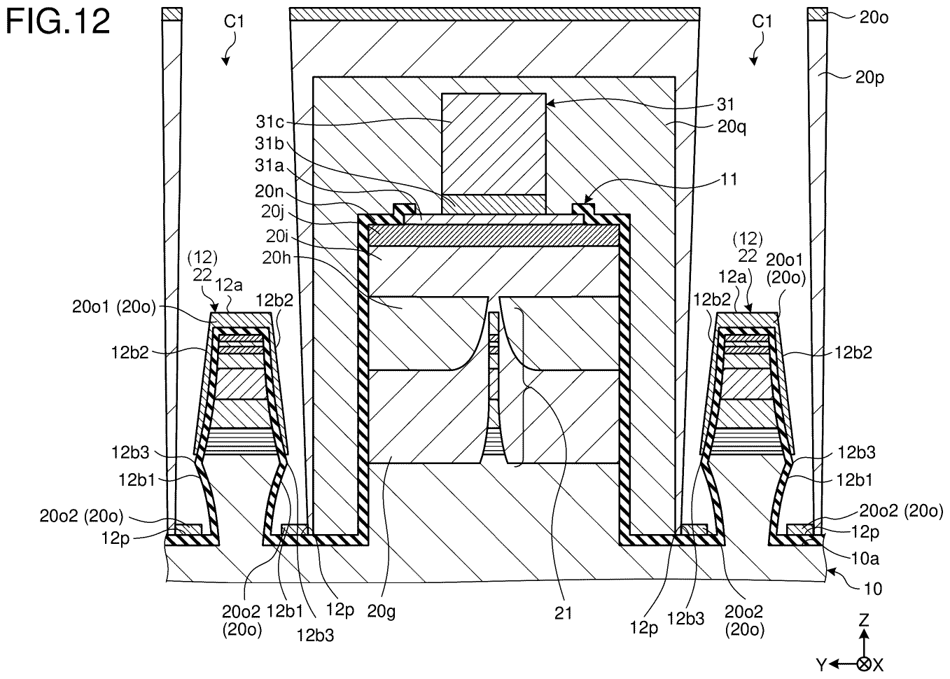

Subsequently, as illustrated in FIG. 12, in the apex portion of the first protrusion 11, after the insulating film 20n is partially removed, the apex portion is covered by enveloping layers 20p and 20q; and concave portions C1 are formed when the enveloping layer 20p is partially removed by means of etching using a resist (not illustrated). The concave portions C1 are formed in such a way that the second protrusions 12 and the surrounding portions 12p thereof are exposed within the corresponding concave portions C1. Then, the metallic layer 200 is subjected to vapor deposition, so that the metallic layer 2001, which covers the top face 12a and the lateral faces 12b2 of the second protrusions 12, and the metallic layer 2002, which covers the surrounding portions 12p of the second protrusions 12, are formed inside the concave portions C1.

Then, the enveloping layers 20p and 20q are removed, and the metallic layer 200 present on the enveloping layer 20p is removed. Subsequently, as illustrated in FIG. 1, after the end face of the substrate 10 in the opposite direction of the Z direction is polished and the face 10b is formed, the electrode 32 is formed on the face 10b using, for example, the vapor-deposition liftoff technique. Subsequently, for example, heat treatment at about 400° C. is performed, and ohmic connection is performed among the electrode 31, the electrode 32, and the semiconductor layers of the first protrusion 11. Moreover, the lateral faces of the first protrusion 11 are covered by the insulating film 20n.

The wafer (not illustrated) that has been subjected to the abovementioned processing is cleaved. Then, low-reflectivity coating is performed on the end face 11c in the X direction (see FIG. 2), and high-reflectivity coating is performed on the end face in the opposite direction of the X direction. As a result, the optical semiconductor device 100 illustrated in FIGS. 1 and 2 reaches completion.

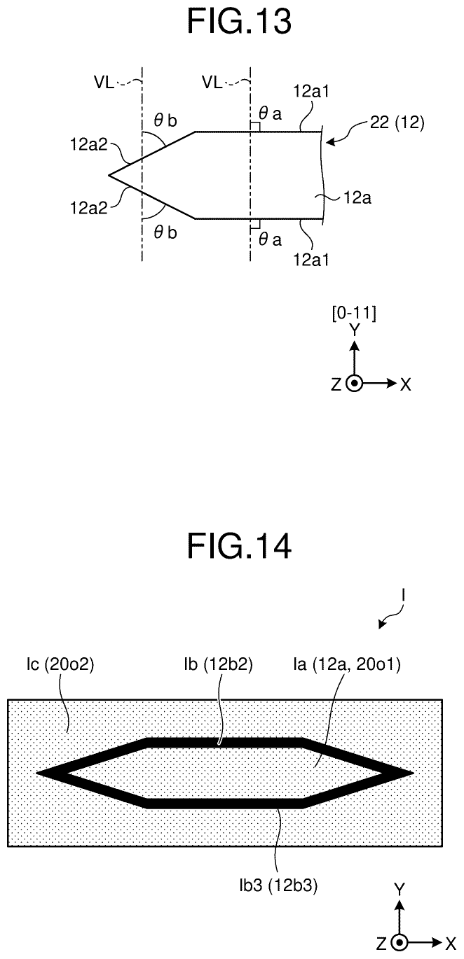

FIG. 13 is a planar view of the second protrusion 12. As illustrated in FIG. 13, in the planar view from the opposite direction of the Z direction, the top face 12a of the second protrusion 12 has a polygonal shape. The shape of the top face 12a is decided according to the planar shape of the etch stop layer involved in the etching after the state illustrated in FIG. 10, that is, according to the planar shape of the sixth layer 20f according to the first embodiment. The planar shape of the sixth layer 20f of the mesa 22 is decided according to the planar shape of the mask layer 20m2 during the etching performed to obtain the product material illustrated in FIG. 8 from the product material illustrated in FIG. 5, that is, according to the planar shape of the mask layer 20m2 illustrated in FIGS. 6 and 7. Thus, in the planar view from the opposite direction of the Z direction as illustrated in FIG. 13, the planar shape of the top face 12a is similar to the planar shape of the mask layer 20m2 illustrated in FIGS. 6 and 7. More particularly, regarding the top face 12a, sides 12a1 extend in the substantially same direction as the sides 20ma of the mask 20m2, and sides 12a2 extend in the substantially same direction as the sides 20mb of the mask layer 20m2. Thus, the sides 12a1 and 12a2 too are not parallel to the virtual lines VL extending in the [0-11] direction (the Y direction). More particularly, the minimum angle θa made by each side 12al, which runs substantially along the X direction, with the virtual line VL has the absolute value substantially equal to 90°. Moreover, the minimum angle θb made by each side 12a2, which constitutes an apical portion in the X direction and the opposite direction of the X direction, with the virtual line VL has the absolute value substantially equal to 70°.

When the inventors performed exhaustive experimental research, it turned out that, when the sides 20mb of the mask layer 20m2 are substantially parallel to the [0-11] direction, during the etching performed to obtain the product material illustrated in FIG. 11 from the product material illustrated in FIG. 10, unintended projections (not illustrated, hereinafter referred to as unnecessary projections) get formed on the lateral faces 12b2 of the second protrusions 12 due the unetched residual part.

As a result of diligently performing the research, the inventors found that unnecessary projections are formed when a side 20mc constituting the polygonal shape of the mask layer 20m2 is substantially parallel to the virtual lines VL. The inventors estimated that, when the wafer representing the substrate 10 and the semiconductor layers have a zinc blende structure, the formation of unnecessary projections has a correlation with the crystalline orientation of the zinc blende structure. In that regard, as a result of performing exhaustive experimental research, the inventors found that, from the perspective of not encountering unnecessary projections, the sides 20ma and 20mb of the mask layer 20m2 need to be non-parallel to the virtual lines VL, and the minimum angle made by the sides 20ma and 20mb with the vertical lines VL is desirably equal to or greater than 45°.

As explained above, the sides 12a1 and 12a2 of the top face 12a of each second protrusions 12 extend along the sides 20ma and 20mb of the mask layer 20m2. Hence, from the perspective of not encountering unnecessary projections, the sides 12a1 and 12a2 need to be non-parallel to the virtual lines VL, and the minimum angle made by the sides 12a1 and 12a2 with the vertical lines VL is desirably equal to or greater than 45°. Such a shape of the top face 12a constitutes evidence of the planar shape of the mask layer 20m2.

In FIG. 14 is illustrated an example of an image I which is taken in the opposite direction of the Z direction and which captures the second protrusion 12 serving as an alignment marker. Based on the image processing performed with respect to the image I, within a plane intersecting with the Z direction of a predetermined coordinate system, the position and the orientation (direction) of the second protrusion 12 is calculated, and in turn the position and the orientation of the optical semiconductor device 100 is calculated. Herein, the second protrusion 12 represents an example of a salient portion.

As illustrated in FIG. 14, the image I includes: a low-luminance region Ib corresponding to the lateral face 12b2, and a high-luminance region Ic corresponding to the metallic layer 2002 that covers the surrounding portion 12p.

As illustrated in FIG. 1, the top face 12a and the surrounding portion 12p are facing toward the Z direction. As a result, in the image I illustrated in FIG. 14, the top face 12a and the surrounding portion 12p represent high-luminance regions Ia and Ic, respectively. The top face 12a and the surrounding portion 12p are covered by the metallic layer 200. Hence, in the image I, the luminance of the high-luminance regions Ia and Ic may be further enhanced, thereby enabling further enhancement in the distinguishability of the high-luminance regions Ia and Ic during the image processing of the image I.

Moreover, as is clear from dash-double-dot lines illustrated in FIG. 1 in a corresponding manner to the end edges 12b3 of the lateral faces 12b1, from among the surrounding portions 12p and the metallic layer 2002 that covers the surrounding portions 12p, the region overlapping with the lateral faces 12b1 in the opposite direction of the Z direction remains hidden due to the second protrusion 12 in the line of sight along the opposite direction of the Z direction; and hence that region does not appear in the image I. Thus, from among the surrounding portions 12p and the metallic layer 2002, when seen from the opposite direction of the Z direction, the high-luminance region Ic appears to be adjacent to the end edges 12b3 in the Z direction of the lateral faces 12b1. Herein, a boundary line Ib3 between the high-luminance region Ic and the low-luminance region Ib corresponds to the end edge 12b3.

The lateral faces 12b2 are facing toward the direction D2 that is inclined in the Z direction with respect to the direction orthogonal to the Z direction. Hence, the reflected light coming from the lateral faces 12b2 does not easily fall on the camera, and the lateral faces 12b2 become low-luminance regions. That is, in the first embodiment, because the lateral faces 12b2 is present in between the top face 12a and the lateral faces 12b1, as illustrated in FIG. 14, the low-luminance region Ib happens to be present between the high-luminance regions Ia and Ic. As a result, during the image processing of the image I, it becomes easier to achieve further enhancement in the distinguishability of the high-luminance regions Ia and Ic.

Moreover, as explained above, the lateral faces 12b1 are facing toward the direction D1 that is inclined in the opposite direction of the Z direction with respect to the direction orthogonal to the Z direction. Hence, according to the first embodiment, as compared to the case in which the lateral faces 12b1 are facing toward the direction D2 that is inclined in the Z direction with respect to the direction orthogonal to the Z direction, the end edges 12b3 may be formed as angle sudden-change portions (sharp edges) between the lateral faces 12b1 and 12b2. As a result, in the image I, it becomes possible to prevent wobbling or bending of the boundary line Ib3 attributed to the formation of the end edge 12b3 in a rolling manner. As explained above, the boundary line Ib3 between the high-luminance region Ic and the low-luminance region Ib corresponds to the end edge 12b3. Thus, according to the first embodiment, it becomes possible to further enhance the shape accuracy of the high-luminance region Ic, and in turn it becomes possible to further enhance the detection accuracy of the position of each second protrusion 12 during the image processing of the image I.

Meanwhile, as is clear from FIGS. 1, 2, and 14, the second protrusion 12 has a plurality of lateral faces 12bl extending in directions intersecting with the Z direction; and the lateral faces 12b1 include mutually parallel lateral faces 12b1 and mutually intersecting lateral faces 12b1. As a result, as compared to the case in which there is only a single lateral face 12b1, it becomes possible to further enhance the detection accuracy of the position and the orientation of each second protrusion 12 during the image processing, and to further enhance the detection accuracy of the position and the orientation of each second protrusion 12 in various directions intersecting with the z direction.

As explained above, according to the structure and the method described in the first embodiment, each second protrusion 12 representing an alignment marker has the lateral faces 12b1 and the end edges 12b3. With that, it becomes possible to further enhance the detection accuracy of the positions of the second protrusions 12. That enables obtaining the optical semiconductor device 100 in the new and improved form.

Moreover, in the first embodiment, at least some part of each second protrusion 12 (salient portion) representing an alignment marker may be formed by following the same process as the process for forming the first protrusion 11. Hence, as compared to the case in which the second protrusions 12 are formed by following a different process than the process for forming the first protrusion 11, it becomes possible to form the second protrusions 12 with more ease. Moreover, since the second protrusions 12 may be formed by following the same process as the process for forming the first protrusion 11 that includes the active layer 11a, it becomes possible to further enhance the relative positional accuracy of the second protrusions 12, which represent the alignment markers, with respect to the active layer 11a. In turn, it becomes possible to further enhance the coupling efficiency of the light between the optical semiconductor device 100 and the optical functional device.

Furthermore, according to the first embodiment, regarding the optical semiconductor device 100 and the optical functional device, in the Z direction, that is, in the direction of layering the semiconductor layers in the optical semiconductor device 100, the polygonal sides 20ma and 20mb of the mask layers 20, which are used in the formation of the second protrusions 12, were maintained to be non-parallel to the virtual lines VL; and the minimum angle made by the sides 20ma and 20mb with the virtual lines VL was maintained to be equal to or greater than 45°. As a result, the sides 12a1 and 12a2 of the top face 12a of each second protrusion 12 are maintained to be non-parallel with the virtual lines VL, and the minimum angle made by the sides 12a1 and 12a2 with the virtual lines was maintained to be equal to or greater than 45°. Hence, on the lateral faces 12b2 of each second protrusion 12, the formation of unnecessary projections may be held down, and in turn any obstruction in the alignment of the optical functional device caused by unnecessary projections may be held down. That is, according to the first embodiment, as a result of forming the second protrusions 12 with more accuracy, the required alignment accuracy between the optical semiconductor device 100 and the optical functional device may be secured in a more reliable manner. In turn, the required coupling efficiency of the light between the optical semiconductor device 100 and the optical functional device may be secured in a more reliable manner. Moreover, since the process for removing unnecessary projections becomes redundant, it becomes possible to hold down an increase in the efforts and the cost for manufacturing the optical semiconductor device 100.

### Second Embodiment

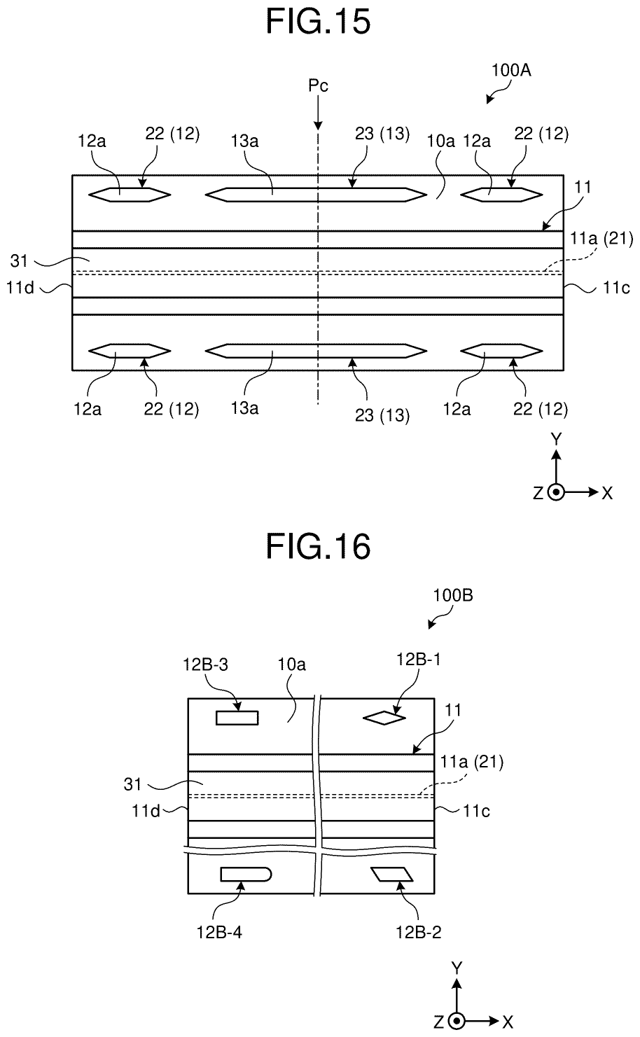

FIG. 15 is a planar view of an optical semiconductor device 100A according to a second embodiment. The optical semiconductor device 100A according to the second embodiment has an identical configuration to the optical semiconductor device 100 according to the first embodiment, and identical actions and identical effects may be achieved based on the identical configuration.

However, as illustrated in FIG. 15, the second embodiment differs from the first embodiment in the way that the second protrusions 12 have a different shape and a different arrangement and that third protrusions 13 including a mesa 23 are further included.

The second protrusion 12 are arranged closer to the end face 11c than to a central position Pc (central portion) in the X direction. The end face 11c represents the end portion from which the optical semiconductor device 100A outputs the laser light and serves as that part in the optical semiconductor device 100A which enables achieving the coupling accuracy of the light with the optical functional device. Thus, as described in the second embodiment, since the second protrusions 12 representing the alignment markers are positioned closer to the end face 11c than to the central position Pc, it becomes easier to enhance the alignment accuracy between the end face 11c and the optical functional device, and in turn it becomes easier to enhance the coupling accuracy of the light between the optical semiconductor device 100A and the optical functional device.

In the optical semiconductor device 100A, a plurality of second protrusions 12 (as an example, in the second embodiment, two second protrusions 12) are included as the second protrusions 12 formed closer to the end face 11c than to the central position Pc. Moreover, in the optical semiconductor device 100A, a plurality of second protrusions 12 (as an example, in the second embodiment, four second protrusions 12) are included as the second protrusions 12 closer to the end face 11c or the end face 11d than to the central position Pc. Hence, according to the second embodiment, based on the image processing performed on the image I in which a plurality of second protrusions 12 is captured as the alignment markers, the position and the direction (orientation) of the optical semiconductor device 100A may be set with more accuracy.

The third protrusions 13 represent alignment members that make contact with the optical functional device, and enable alignment of the optical semiconductor device 100A and the optical functional device in the Z direction. The mesas 23 have an identical laminate structure to the mesas 21 and 22. Thus, according to the second embodiment, at least some part of the third protrusions 13 may be formed by following the same process as the process for forming the first protrusion 11 and the second protrusions 12. Hence, as compared to the case in which the third protrusions 13 are formed by following a different process than the process for forming the first protrusion 11 and the second protrusions 12, the third protrusions 13 may be formed with more ease and in turn the optical semiconductor device 100A may be formed with more ease. The mesa 23 may be referred to as third mesas. Meanwhile, in the second embodiment, since the third protrusions 13 may be formed by following the same process as the process for forming the first protrusion 11 that includes the active layer 11a, it becomes possible to further enhance the relative positional accuracy of the third protrusions 13 with respect to the active layer 11a. In turn, it becomes possible to further enhance the coupling efficiency of the light between the optical semiconductor device 100A and the optical functional device.

### Third Embodiment

FIG. 16 is a planar view of an optical semiconductor device 100B according to a third embodiment. The optical semiconductor device 100B according to the third embodiment has an identical configuration to the optical semiconductor devices 100 and 100A according to the embodiments described earlier, and identical actions and identical effects may be achieved based on the identical configuration.

However, as illustrated in FIG. 16, in the third embodiment, second protrusions 12B-1 to 12B-4 have different shapes than the shape according the embodiments described earlier. The second protrusion 12B-1 has a rhombic shape in the planar view from the opposite direction of the Z direction. The second protrusion 12B-2 has the shape of a parallelogram in the planar view. The second protrusion 12B-3 has a quadrilateral shape in the planar view. The second protrusion 12B-4 has a partially-curved shape in the planar view. In this way, various polygonal shapes or various shapes other than polygonal shapes may be adapted as the shapes of the second protrusions 12B-1 to 12B-4. Meanwhile, in case unnecessary projections are formed in the shapes of the second protrusions 12B-1 to 12B-4, then a process for removing that unnecessary projection may be added.

Herein, the shapes of the second protrusions 12B-1 to 12B-4 illustrated in FIG. 16 are only exemplary, and may be modified to various other shapes. Moreover, when the optical semiconductor device 100B includes a plurality of second protrusions, some of the second protrusions may have the same shape or similar shapes.

### Fourth Embodiment

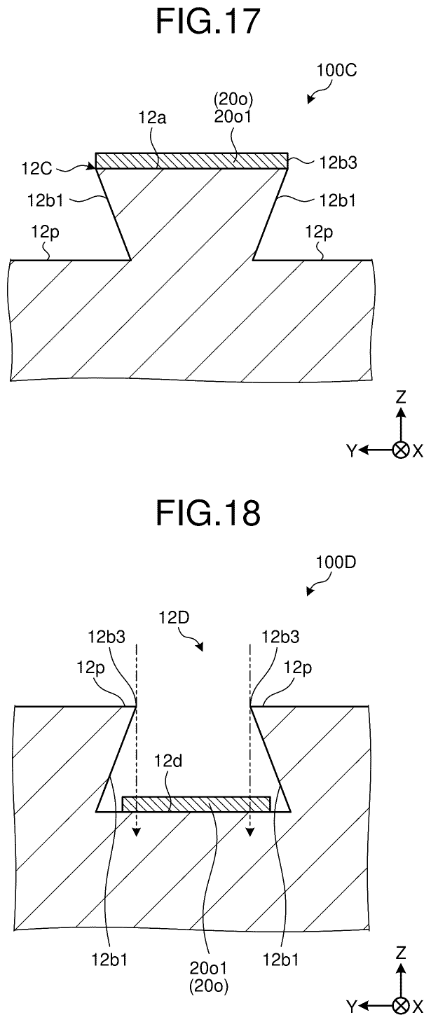

FIG. 17 is a cross-sectional view of that part of an optical semiconductor device 100C according to a fourth embodiment which includes a second protrusion 12C. The optical semiconductor device 100C according to the fourth embodiment has an identical configuration to the optical semiconductor devices 100, 100A, and 100B according to the embodiments described earlier, and identical actions and identical effects may be achieved based on the identical configuration.

As illustrated in FIG. 17, in the fourth embodiment, the second protrusion 12C has the top face 12a and the lateral faces 12b1, but does not have the lateral faces 12b2. Moreover, the metallic layer 2001 that covers the top face 12a is adjacent to the end edges 12b3 in the Z direction of the lateral faces 12b1. In this case too, each end face 12b3 may be formed as the angle sudden-change portion (sharp edge) between the corresponding lateral face 12b1 and the top face 12a. Hence, in the fourth embodiment too, in an identical manner to the first embodiment described earlier, in an image (not illustrated), it becomes possible to prevent wobbling or bending of the boundary line attributed to the formation of the end edges 12b3 in a rolling manner. Thus, it becomes possible to further enhance the shape accuracy of the high-luminance region corresponding to the top face 12a (the metallic layer 20o1), and in turn it becomes possible to further enhance the detection accuracy of the position and the orientation of each second protrusion 12 during the image processing of the image. Meanwhile, a metallic layer may be provided to cover each surrounding portion 12p. In that case, the metallic layer 2001 that covers the top face 12a need not be provided.

### Fifth Embodiment

FIG. 18 is a cross-sectional view of that part of an optical semiconductor device 100D according to a fifth embodiment which includes a depressed portion 12D. The optical semiconductor device 100D according to the fifth embodiment has an identical configuration to the optical semiconductor devices 100, 100A, 100B, and 100C according to the embodiments described earlier, and identical actions and identical effects may be achieved based on the identical configuration.

As illustrated in FIG. 18, in the fifth embodiment, instead of using salient portions such as the second protrusions 12 as the alignment markers, the depressed portion 12D is included as the alignment marker. For example, the depressed portion 12D may be provided at various locations in the optical semiconductor device 100D, such as the bottom face of the depressed portions (trenches) between the first protrusion 11 and the second protrusions 12, or the top face 12a of the salient portions such as the second protrusions according to the embodiments described earlier.

The depressed portion 12D has a bottom face 12d and has a plurality of lateral faces including the two lateral faces 12b1 positioned on the anterior side and the posterior side of the bottom face 12d in the Y direction. The lateral faces 12b1 are positioned in a shifted manner in the Z direction with respect to the bottom face 12d. Herein, the bottom face 12d represents an example of a bottom portion.

As is clear from a dash-double-dot line drawn corresponding to the end edge 12b3 representing the opening edge of the depressed portion 12D in FIG. 18, from among the bottom face 12d and the metallic layer 2001 that covers the bottom face 12d, the region overlapping with the lateral faces 12b1 in the opposite direction of the Z direction remains hidden due to the surrounding portions 12p of the opening of the depressed portion 12D in the line of sight along the opposite direction of the Z direction; and hence that region does not appear in the image. Thus, from among the bottom face 12d and the metallic layer 2002, when seen from the opposite direction of the Z direction, the high-luminance region in the image appears to be adjacent to the end edges 12b3 in the Z direction of the lateral faces 12b1.

In the fifth embodiment too, each end face 12b3 may be formed as the angle sudden-change portion (sharp edge) between the corresponding lateral face 12b1 and the corresponding surrounding portion 12p. Hence, in the fifth embodiment too, in an identical manner to the first embodiment described earlier, in an image (not illustrated), it becomes possible to prevent wobbling or bending of the boundary line attributed to the formation of the end edges 12b3 in a rolling manner. Thus, it becomes possible to further enhance the shape accuracy of the high-luminance region corresponding to the bottom face 12d (the metallic layer 20o1), and in turn it becomes possible to further enhance the detection accuracy of the position and the orientation of the depressed portion 12D during the image processing of the image. Meanwhile, a metallic layer may be provided to cover the surrounding portions 12p. In that case, the metaling layer 2001 that covers the bottom face 12d need not be provided.

While certain embodiments have been described, those embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure. Moreover, regarding the constituent elements, the specifications about the configurations and the shapes (structure, type, direction, model, size, length, width, thickness, height, number, arrangement, position, material, etc.) may be suitably modified.

For example, the optical semiconductor device may be a different optical module, such as a semiconductor optical amplifier, than a semiconductor laser device.

Moreover, for example, the metallic layer need not be used to cover the top portion, the bottom portion, or the surrounding portion in entirety. That is, as long as the metallic layer covers at least some part, it serves the purpose.

According to the present disclosure, it becomes possible to provide a new and improved optical semiconductor device and to provide a manufacturing method for the optical semiconductor device.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical semiconductor device comprising:
a substrate;
a first protrusion protruding from the substrate in a first direction, the first protrusion including a first mesa having a laminate structure, in which a plurality of semiconductor layers are layered on the substrate in the first direction, the first mesa including an active layer as one of the semiconductor layers; and
an alignment marker provided either as a salient portion which protrudes with respect to surrounding portion in the first direction or as a depressed portion which is depressed in an opposite direction of the first direction, the alignment marker being configured to identify a position of the optical semiconductor device in a direction intersecting with the first direction, wherein
the alignment marker is shifted with respect to top portion of the salient portion in opposite direction of the first direction, or is shifted in the first direction with respect to a bottom portion of the depressed portion, and
the alignment marker includes a first lateral face which is facing toward a direction inclined in an opposite direction of the first direction with respect to a direction orthogonal to the first direction.

2. The optical semiconductor device according to claim 1, further comprising a metallic layer configured to cover at least some part of at least either top portion of the salient portion, or the bottom portion of the depressed portion, or the surrounding portion, the metallic layer including, when viewed from opposite direction of the first direction, a region adjacent to end edge in the first direction of the first lateral face.

3. The optical semiconductor device according to claim 1, wherein the alignment marker is adjacent to opposite side of the substrate with reference to the first lateral face, and has a second face that is facing toward a direction inclined in the first direction with respect to the direction orthogonal to the first direction.

4. The optical semiconductor device according to claim 1, wherein the alignment marker includes a plurality of alignment markers.

5. The optical semiconductor device according to claim 4, wherein the first protrusion is positioned in between the plurality of alignment markers.

6. The optical semiconductor device according to claim 1, further comprising an end face configured to either output light or receive input of light as an end portion in a second direction intersecting with the first direction, wherein
the alignment marker is positioned closer to the end face than to s central portion of the optical semiconductor device in the second direction.

7. The optical semiconductor device according to claim 1, wherein the alignment marker includes a plurality of first lateral faces as the first lateral face.

8. The optical semiconductor device according to claim 7, wherein the alignment marker includes, as the plurality of first lateral faces, a plurality of first lateral faces extending substantially parallel to directions intersecting with the first direction.

9. The optical semiconductor device according to claim 7, wherein the alignment marker includes, as the plurality of first lateral faces, a plurality of first lateral faces extending in directions intersecting with the first direction and intersecting with each other.

10. The optical semiconductor device according to claim 1, wherein an alignment marker disposed as the salient portion is included as the alignment marker.

11. The optical semiconductor device according to claim 10, wherein the salient portion protrudes from the substrate in the first direction and at a position separated from the first protrusion in a third direction intersecting with the first direction, and has a same laminate structure as the first mesa.

12. The optical semiconductor device according to claim 10, wherein
the substrate includes a surface representing a (100) face, and
top face of the salient portion in the first direction includes sides that are not parallel to a virtual line extending in [0-11] direction.

13. The optical semiconductor device according to claim 12, wherein a minimum angle made by each side of the salient portion with the virtual line is equal to or greater than 45°.

14. A manufacturing method for an optical semiconductor device, comprising:
forming, on a substrate, a laminate structure in which a plurality of semiconductor layers are layered in a first direction, the plurality of semiconductor layers including a first semiconductor layer made of a material functioning as an active layer;
forming a plurality of mesas protruding from the substrate at a plurality of locations separated in a third direction intersecting with the first direction by partially removing the laminate structure on an opposite side of the structure;
forming a current inhibition layer in order to fill a space among the plurality of mesas;
forming a conductor layer on the opposite side of the substrate with respect to the first semiconductor layer; and
forming a first protrusion including: a first mesa representing one of the plurality of mesas; a part of the current inhibition layer that is adjacent to the first mesa; and a part of the conductor layer that is present on the opposite of the substrate with respect to the first mesa, and forming a second protrusion including a second mesa representing one of the plurality of mesas, the second protrusion functioning as an alignment marker configured to identify a position of the optical semiconductor device in a direction intersecting with the first direction, wherein
the alignment marker is shifted with respect to a top portion of the second protrusion in the opposite direction of the first direction, and
the alignment marker includes a first lateral face which is facing toward a direction inclined in the opposite direction of the first direction with respect to a direction orthogonal to the first direction.

15. The manufacturing method for the optical semiconductor device according to claim 14, wherein
a surface of the substrate is a (100) face,
the forming of the plurality of mesas includes forming the second mesa by performing etching using a mask, and
in planar view from opposite direction of the first direction, the mask has a polygonal shape with each side being non-parallel to a virtual line extending in [0-11] direction.
